(19) United States
(12) Patent Application Publication
(10) Pub. No.: US 2022/0051899 A1
(43) Pub. Date: Feb. 17, 2022

(54) ETCHING METHOD AND ETCHING APPARATUS

(71) Applicant: Tokyo Electron Limited, Tokyo (JP)

(72) Inventors: Ryutaro SUDA, Miyagi (JP); Maju TOMURA, Miyagi (JP)

(21) Appl. No.: 17/444,605

(22) Filed: Aug. 6, 2021

Related U.S. Application Data
(60) Provisional application No. 63/066,403, filed on Aug. 17, 2020.

(30) Foreign Application Priority Data
Jul. 2, 2021 (JP) 2021-110813

(51) Int. Cl. H01L 21/3065; H01L 21/311; H01J 37/32

(52) U.S. Cl. CPC H01L 21/3065; H01L 21/31116; H01J 2237/334; H01J 37/32724; H01J 37/32183

(57) ABSTRACT

An etching method is provided that includes: (a) providing a substrate including an etching target film on a substrate support stage arranged in a process chamber; (b) setting a temperature of the substrate support stage; (c) generating plasma from an etching gas;(d) increasing the temperature of the substrate; (e) decreasing the temperature of the substrate; and (f) repeating (d) and (e) a predetermined number of times.

### CROSS-REFERENCE TO RELATED APPLICATION

The present application claims the benefit under 35 U.S.C. § 119 of Provisional Application No. U.S. 63/066,403, filed Aug. 17, 2020, is based upon and claims priority to Japanese Patent Application No. 2021-110813, filed on Jul. 2, 2021, the entire contents of which are incorporated herein by reference.

### BACKGROUND

### 1. Field

The present disclosure relates to an etching method and an etching apparatus.

### 2. Background Art

A method of forming a hole or the like in a silicon oxide film by etching in a low temperature environment has been proposed (See, for example, Patent Document). The higher the aspect ratio, the more likely it is a phenomenon called depth loading occurs in which the etching rate decreases due to the fact that the reaction product generated by the etching accumulates at the bottom of the hole or the like and does not easily volatilize.

### PRIOR ART DOCUMENT

### Patent Document

[Patent Document 1] Japanese Laid-open Patent Publication No. H7-22393

The resent disclosure provides a technique that can promote etching while suppressing the occurrence of depth loading.

### SUMMARY

According to one aspect of the present disclosure, an etching method is provided that includes: (a) providing a substrate including an etching target film on a substrate support stage arranged in a process chamber; (b) setting a temperature of the substrate support stage; (c) generating plasma from an etching gas; (d) increasing the temperature of the substrate; (e) decreasing the temperature of the substrate; and (f) repeating (d) and (e) a predetermined number of times.

According to one aspect, it is possible to promote etching while suppressing the occurrence of depth loading.

### BRIEF DESCRIPTION OF THE DRAWINGS

FIG. 1 is a diagram illustrating an example of an etching model according to an embodiment;

FIG. 2 is a graph illustrating an example of experimental results by an etching method according to first and second embodiments;

FIG. 3 is a flowchart illustrating an example of an etching method according to a third embodiment;

FIG. 4 is a time chart illustrating an example of an etching method according to a fourth embodiment;

FIG. 5 is a diagram that depicts the etching method of FIG. 4;

FIG. 6 is a time chart illustrating an example of an etching method according to a fifth embodiment;

FIGS. 7A and 7B illustrate a time chart illustrating an example of an etching method according to a sixth embodiment; and

FIG. 8 is a cross-sectional view illustrating an example of an etching apparatus according to an embodiment.

### DESCRIPTION OF THE EMBODIMENTS

In the following, embodiments for carrying out the present disclosure will be described with reference to the drawings. In each drawing, the same components are indicated by the same reference numerals and overlapping descriptions may be omitted.

### Depth Loading and Etching

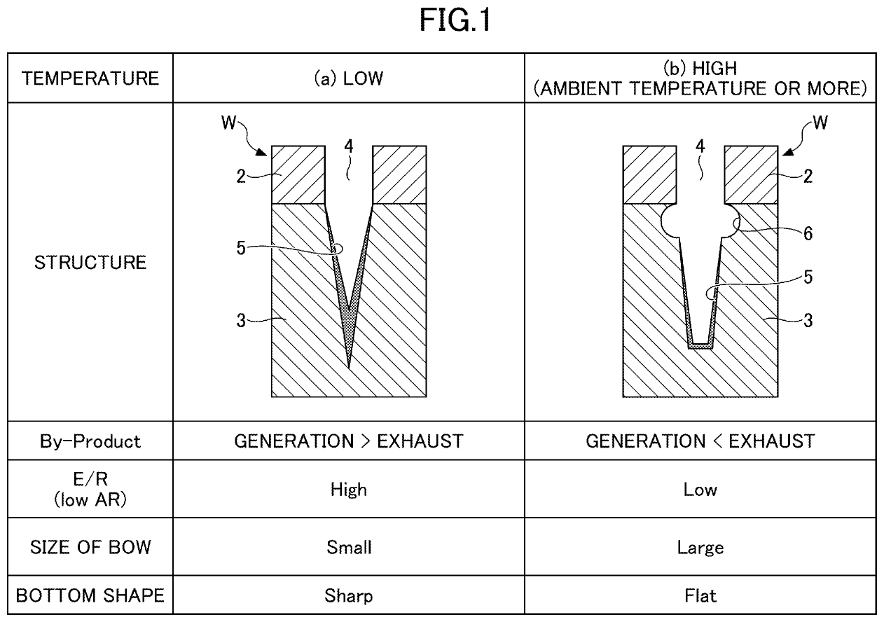

First, a decrease in the etching rate due to Depth Loading will be described with reference to FIG. 1. FIG. 1 is a diagram illustrating an example of an etching model (structure) according to an embodiment. In the etching model according to the embodiment, a substrate W includes an etching target film 3 and a mask 2. The etching target film 3 is etched through a pattern formed on the mask 2, thereby forming a hole or groove (hereinafter, referred to as a recess 4) on the etching target film 3.

When the aspect ratio of the recess 4 (AR: Aspect Ratio) becomes about 20 or more with the passage of the etching time, a phenomenon called depth loading occurs in which a reaction product (By-Product) generated at the bottom of the recess 4 by the etching is not easily discharged and the etching rate is lowered. The phenomenon of depth loading is remarkable when the aspect ratio is 50 or more. Hereinafter, in the present specification, an aspect ratio of 20 or more is referred to as a high aspect ratio, and an aspect ratio of less than 20 is referred to as a low aspect ratio. At the bottom of the recess 4 with a high aspect ratio, the pressure is higher than at the bottom of the recess 4 with a low aspect ratio, and therefore the depth loading effect is large.

For example, in HARC (High Aspect Ratio Contact), the deeper the recess 4, the more difficult it is to discharge the reaction product at the recess 4, causing depth loading and deteriorating the throughput. The shape of the bottom of the recess 4 is also deteriorated.

FIG. 1(a) schematically illustrates etching in a case in which the temperature of the substrate is lower than an ambient temperature. FIG. 1(b) schematically illustrates etching in a case in which the temperature of the substrate is high (ambient temperature or more). In a case in which the temperature of the substrate is lower than an ambient temperature, the amount of etchant adsorbed onto the substrate (the amount of reactive species generated) increases. In this case, the etching rate (E/R) is high in the region of the low aspect ratio (low AR). Also, because the etching is promoted, although the amount of the reaction product 5 generated during the etching is large, the discharge rate of the reaction product 5 from the recess 4 is slow. Therefore, as illustrated in the model (structure) in FIG. 1(a), the reaction product 5 is difficult to be discharged, and the depth loading becomes remarkable in the high aspect ratio region. Also, the shape of the recess 4 may be deteriorated, the bottom of the recess 4 may be sharpened, the side wall of the recess 4 may not be vertical, and the shape of the recess 4 may be twisted. However, a Bowing shape in which the side wall of the recess 4 widens with respect to the frontage of the etching target film 3 is unlikely to occur.

The higher the temperature of the substrate, the easier the reaction product 5 to volatilize, and the reaction product 5 is discharged from the recess 4 as illustrated in the model of FIG. 1(b), but the amount of the etchant adsorbed on the bottom of the recess 4 is reduced, and the etching rate is not increased. The bottom of the recess 4 is flat, and the side wall of the recess 4 is almost perpendicular. However, the bowing shape 6 is easily generated in the recess 4.

### Embodiment

Thus, depending on the balance between the promotion of etching (generation of the reaction product 5) and the discharge of the reaction product 5 from the recess 4, the occurrence of depth loading, the magnitude of the etching rate, and the shape of the recess 4 are determined. Accordingly, for an etching method according to one embodiment, an etching method is proposed to promote etching while suppressing an occurrence of depth loading even in a high aspect ratio region and to suppress tapering of the tip of the recess 4 to make it vertical.

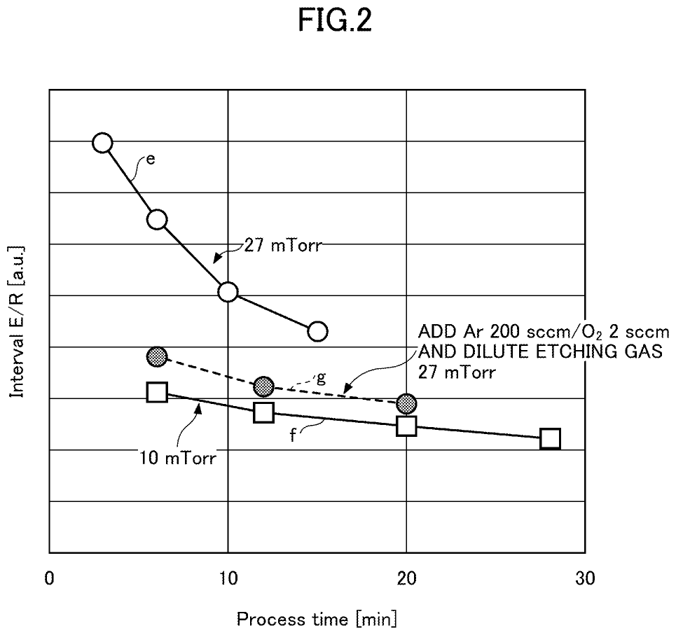

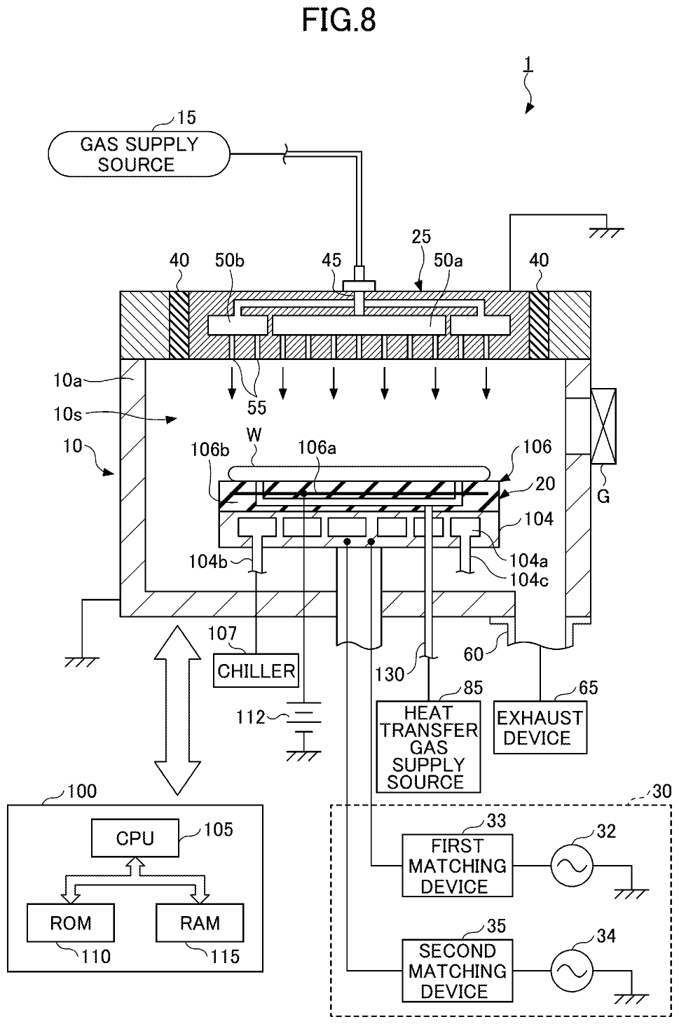

FIG. 2 is a graph illustrating an example of experimental results by an etching method according to one embodiment. In this experiment, using an etching apparatus 1 (see FIG. 8) which will be described later below, a substrate W including an etching target film was placed on a substrate support stage 20 arranged in a process chamber 10 and etched. During the experiment, etching was performed while supplying an etching gas was into the process chamber 10 and controlling the temperature of the substrate support stage 20 according to the following conditions.

### Conditions

Etching target film: Layered film in which a silicon oxide film (SiOx) and a silicon nitride film (SiN) are alternately layered

Etching gas: halogen-containing gas, fluorocarbon gas

Temperature of substrate support stage: −40° C.

In the experiment, a case where the inside of the process chamber was controlled to a relatively high pressure (27 mTorr: 3.6 Pa) and etching was performed under the above conditions is indicated by the curve e as a reference example. On the other hand, a case where the inside of the process chamber was controlled to a relatively low pressure (10 mTorr: 1.3 Pa) and etching was performed under the above conditions is indicated by the curve f as a first embodiment. Further, a case where the inside of the process chamber was controlled to a relatively high pressure (27 mTorr), 200 sccm of argon gas and 2 sccm of O₂ gas were added to the etching gas to dilute the etching gas at the time of etching under the above conditions is indicated by the curve g as a second embodiment. It should be noted that the O₂ gas was added to the etching gas to widen the frontage of the recess 4, and the O₂ gas need not be added to dilute the etching gas.

In FIG. 2, the horizontal axis indicates the process time (etching time) and the vertical axis indicates Interval E/R. Interval E/R is indicated by the following formula and corresponds to the etching rate.

Interval E/R=Dₙ−Dₙ₋₁/(tₙ−tₙ₋₁)

In the formula, n indicates the measured point of the etching rate, t indicates time, and D indicates the depth of the recess 4. The time t was calculated as t₀=0 (min) and the depth D was calculated as D₀=0 (nm) with respect to the measurement point of n=1.

As a result, in the curve e of the reference example, Interval E/R sharply decreased with the passage of the process time. It is considered that because the temperature of the substrate support stage 20 in FIG. 8 was as low as −40° C. at the initial stage of the process, the supply amount of etchant was large and Interval E/R was high. Also, although interval E/R was high and the amount of reaction product generated was increased, the recess 4 became deeper with the passage of the process time, and therefore, the pressure in the process chamber 10 became high and the reaction product was not easily discharged from the recess 4. From the above, it is considered that as the process time became longer, depth loading occurred, and the decrease in Interval E/R (decrease in etching rate) became remarkable.

On the other hand, in the curve f of the first embodiment and the curve g of the second embodiment, a sharp decrease in Interval E/R as in the reference example did not occur, and the decrease in the etching rate relative to the process time was gentle. That is, in the curve f of the first embodiment, because the pressure in the process chamber 10 was controlled to be lower than that of the reference example, the reaction product was easily discharged from the bottom of the recess 4, and the occurrence of depth loading could be suppressed, and the decrease in the etching rate was gentle. Also, in the curve g of the second embodiment, the etchant was diluted by argon gas, and the supply amount of the etchant to the substrate was reduced compared to the reference example, thereby reducing the amount of reaction product generated. Therefore, the occurrence of depth loading was suppressed, and the decrease in the etching rate was gentle.

In the reference example, Interval E/R decreases rapidly as the process time passes. Thus, for example, in a case in which the etching target film 3 is etched in a pattern of the mask 2 having different diameters or widths, the difference in etching rates of the recesses 4 having different diameters or widths may become large. On the other hand, by lowering the pressure in the etching method of the first embodiment and diluting the etching gas in the etching method of the second embodiment, the amount of change in the etching rates of the recesses 4 having different diameters or widths is reduced. Therefore, according to the etching methods of the first and second embodiments, for example, even in a case in which the etching target film 3 is etched in a pattern of the mask 2 having different diameters or widths, the difference in the etching rates of the recesses 4 having different diameters or widths can be reduced, and the decrease in the etching rate with the lapse of the process time can be moderated.

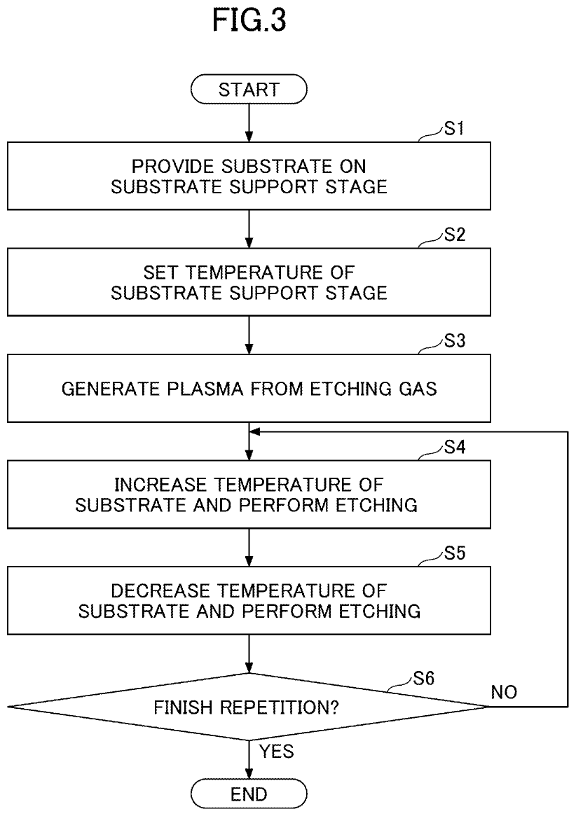

However, in the etching methods of the first and second embodiments, the overall etching rate was lower than that of the reference example, and the etching rate tended to be low especially at the initial stage of etching (low aspect ratio region). Thus, the inventors of the present disclosure have derived an etching method that does not reduce the overall etching rate and does not cause a sharp decrease in the etching rate. FIG. 3 is a flowchart illustrating an example of an etching method according to a third embodiment. In the present specification and drawings, within radio frequencies (RF), a radio frequency that is supplied to the substrate support stage 20 or an electrode facing the substrate support stage 20 and that has a frequency that mainly contributes to plasma generation is referred to as HF. Also, a radio frequency that is supplied to the substrate support stage 20 and that has a frequency that mainly contributes to the attraction of ions in the plasma is referred to as LF. The frequency of HF is higher than the frequency of LF. Each of HF and LF may supplied in the form of pulse. HF electric power is also referred to as source electric power and LF electric power is also referred to as bias electric power.

As illustrated in FIG. 3, the etching method according to the third embodiment includes steps S1 to S6. First, in step S1, a substrate W including an etching target film 3 is provided on the substrate support stage 20 arranged in the process chamber 10. Next, in step S2, the temperature of the substrate support stage 20 is set. In one example, it is preferable that the temperature of the substrate support stage 20 is set to be −40° C. or more and 20° C. or less in step S2. For example, the temperature of the substrate support stage 20 is set to be −40° C. In step S2, the temperature of the substrate may be set instead of setting the temperature of the substrate support stage 20. It is preferable that the temperature of the substrate is set to be −40° C. or more and 20° C. or less. Here, by supplying a heat transfer gas between the top surface of the substrate support stage 20 and the back surface of the substrate, the temperature of the substrate support stage 20 and the temperature of the substrate can be substantially the same.

Next, in step S3, HF power (radio frequency power for plasma generation) is supplied to generate plasma from the etching gas supplied to the process chamber 10. Next, in step S4, the temperature of the substrate W is increased and the etching target film 3 is etched using the generated plasma. Next, in step S5, the temperature of the substrate W is lowered and the etching target film 3 is etched using the generated plasma. In step S4, bias power (which may be LF, for example) is supplied to the substrate support stage 20. In step S5, bias power (which may be LF, for example) is not supplied to the substrate support stage 20. Next, in step S6, it is determined whether or not the steps of step S4 and step S5 have been repeated for a predetermined number of times. The predetermined number of times is set in advance to an integer of one or more. In step S6, the steps of step S4 and step S5 are repeatedly executed until it is determined that a predetermined number of steps has been repeated, and when it is determined that the predetermined number of steps has been repeated, the process ends. It should be noted that the order of the steps of step S4 and step S5 may be reversed such that step S4 may be executed after step S5 is executed.

According to the etching method according to the third embodiment, in S3, by generating plasma from the etching gas, the etchant is supplied (adsorbed) to the substrate surface from the generated plasma, and the etching proceeds. At the same time, the reaction product (etching by-product, By-Product) is formed around the bottom of the recess 4.

Next, in step S4, the discharge from the recess 4 of the reaction product generated by raising the temperature of the substrate W to the predetermined temperature is promoted. For example, in step S4, the temperature of the substrate is increased to the temperature at which the reaction product volatilizes. In step S5, the substrate temperature is again lowered and etching is performed. In step S5, because the lower the temperature of the substrate, the easier it is for the etchant to be adsorbed, the temperature of the substrate is lowered to the temperature at which a sufficient amount of the etchant is adsorbed on the substrate. In step S5, the temperature of the substrate may be set to be −40° C. or more and 20° C. or less. The temperature of the substrate in step S4 is higher than the temperature of the substrate set in step S5. It is preferable that the difference in the temperature of the substrate between step S4 and step S5 is 10° C. or more. In step S4, the temperature of the substrate may be set to be 10° C. or more and 30° C. or less.

### Fourth Embodiment to Sixth Embodiment

Next, three methods of fourth to sixth embodiments as specific embodiments of the third embodiment will be described with respect to an etching method performed by a repetitive process of step S4 and step S5 in the etching method illustrated in FIG. 3. In the fourth to sixth embodiments, an example of repeating the process of executing step S4 after step S5 of FIG. 3 is described. However, step S5 may be executed after step S4.

Examples of the HF frequency are 40 MHz, 60 MHz, 100 MHz, and the like, and examples of the LF frequency are 400 kHz, 3 MHz, 13 MHz, and the like, but the frequencies are not limited to these. The voltage for bias that mainly contributes to the attraction of ions is not limited to a radio frequency (RF), and may be a direct current voltage having a negative pulse frequency. The pulse frequency at this time may be 100 kHz or more and 800 kHz or less, and may be 400 kHz as an example. The radio frequency power (RF power) may be set so that HF power (radio frequency power for plasma generation) is 5 kW and LF power (radio frequency power for bias) is 10 kW, and in general, as the aspect ratio increases, the power used increases.

### Fourth Embodiment

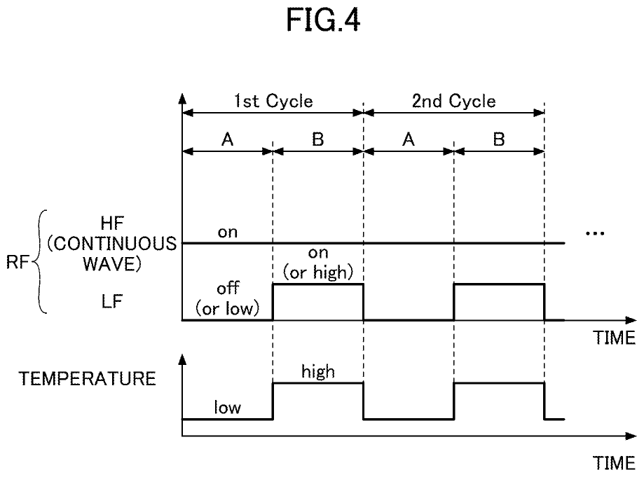

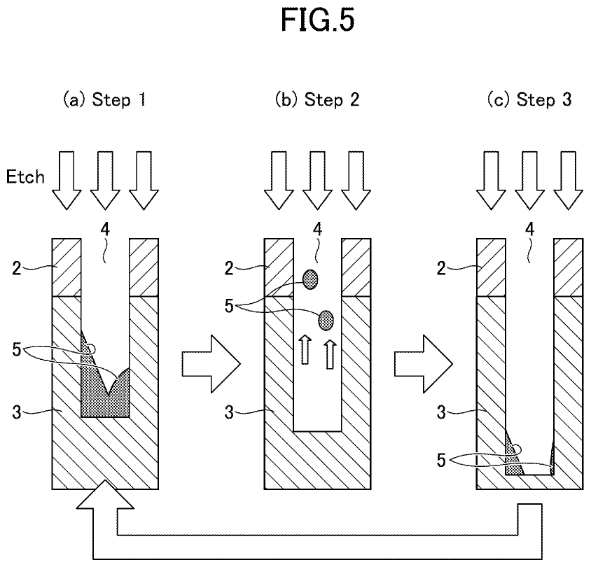

First, an example of an etching method according to the fourth embodiment that is an example of the third embodiment will be described with reference to FIG. 4 and FIG. 5. FIG. 4 is a time chart illustrating an example of the etching method according to the fourth embodiment. FIG. 5 is a diagram that depicts the etching method of FIG. 4.

In the etching method according to the fourth embodiment, HF is a continuous wave and is supplied to the substrate support stage 20 or an electrode (showerhead 25 in FIG. 8) that faces the substrate support stage 20 during etching. By the HF power, plasma is generated from the etching gas, and the etching target film 3 on the substrate W is etched by the plasma.

In the etching method according to the fourth embodiment, LF is a pulse wave and is supplied to the substrate support stage 20 during etching, thereby controlling the temperature of the substrate. In the fourth embodiment, step S5 of FIG. 3 is executed by controlling LF to be Off or low during period A illustrated in FIG. 4. For example, during period A of 1st cycle, LF is controlled to be off or low, and the amount of ions in the plasma drawn to the substrate is reduced, and therefore, the heat input from the plasma is reduced. As a result, the temperature of the substrate decreases. Thereby, the adsorption (supply) of the etchant to the recess 4 can be increased. That is, the lower the temperature of the substrate, the easier it is for the etchant to be adsorbed. Therefore, the temperature of the substrate is lowered to the temperature, at which a sufficient amount of the etchant is adsorbed on the substrate, to promote etching.

Also, step S4 of FIG. 3 is executed by controlling LF to be On or high during period B. During period B of 1st cycle, LF is controlled to be on or high, and the amount of ions in the plasma drawn to the substrate is increased, and therefore, the heat input from the plasma is increased. As a result, the temperature of the substrate rises. This facilitates the desorption of the reaction product 5. That is, as illustrated in Step 2 of FIG. 5(b), the discharge (desorption) of the reaction product by etching generated by increasing the temperature of the substrate W to a predetermined temperature is promoted. However, the supply of the etchant is reduced.

Thus, during period A of next 2nd cycle, LF is again controlled to be off or low. Thereby, the temperature of the substrate is decreased again, the adsorption of the etchant to the recess 4 is increased, and the etching is promoted.

During period B, LF power is controlled so as to increase the temperature of the substrate to a temperature range that volatilizes the reaction product 5 during the etching to be removable from the recess 4. This facilitates the discharge (desorption) of the reaction product. It should be noted that the substrate support stage (mounting stage) is maintained at a temperature of about −40° C. in one example, the temperature of the substrate set during each of period A and period B is saturated by changing with a certain time constant T.

As described above, in the fourth embodiment, by alternately repeating cooling the substrate in period A and increasing the substrate in period B during each cycle, the adsorption and etching of the etchant during period A are promoted and the discharge (desorption) of the reaction product 5 during period B is promoted. This is repeated a predetermined number of times, and by alternately performing the adsorption of the etchant, the promotion of the etching, and the discharge (desorption) of the reaction product, the trade-off between the promotion of the etching and the occurrence of depth loading is eliminated. Thereby, according to the etching method according to the fourth embodiment, the etching can be promoted while suppressing the occurrence of depth loading. As a result, the throughput can be increased. Further, an occurrence of Bowing or twisting at the shape of the recess 4 can be suppressed and the side wall of the recess 4 can be formed to be substantially vertical.

For example, the period of one cycle may be 0.01 milliseconds or more and 10 seconds or less (1 Hz or more and 100 kHz or less at frequency), may be 1 millisecond or more and 1 second or less (1 Hz or more and 1 kHz or less at frequency), or may be 10 milliseconds or more and 500 milliseconds or less (100 Hz or more and 2 Hz or less). The duty cycle (Duty) indicating the time of controlling LF to be on or off with respect to the time of one cycle, i.e., period B/(period A+period B) is preferably 10% or more and 70% or less, and is more preferably 30% or more and 50% or less. The HF frequency, the LF frequency, the period (frequency) of one cycle, the duty cycle, and the like as described may also be similarly applied to fifth and sixth embodiments, which will be described later below. It should be noted that as for the relationship between “high” and “low” in the present disclosure, “high” means a level (power level) higher than that of “low”. In other words, in a case in which “high” is a first level and “low” is a second level, the first level is higher than the second level.

### Fifth Embodiment

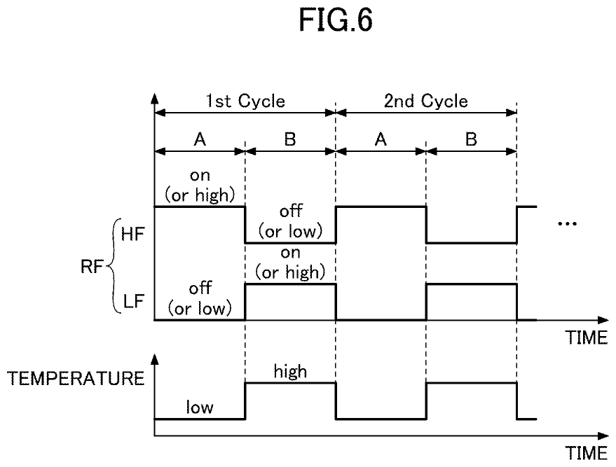

Next, an example of an etching method according to the fifth embodiment that is an example of the third embodiment will be described with reference to FIG. 6. FIG. 6 is a time chart illustrating an example of the etching method according to the fifth embodiment. The etching method according to the fifth embodiment is different from the fourth embodiment in that HF is pulse controlled.

The point of pulse-controlling LF is the same as that of the fourth embodiment, and LF is controlled to be off or low during period A and LF is controlled to be on or high during period B. In addition, in the fifth embodiment, HF is controlled to be on or high during period A and HF is controlled to be off or low during period B. It should be noted that HF is supplied to the substrate support stage 20 or an electrode facing the substrate support stage 20.

Accordingly, during period A of 1st cycle, LF is controlled to be off or low, and the amount of ions in the plasma drawn to the substrate is reduced, and therefore, the heat input from the plasma is reduced. As a result, the temperature of the substrate decreases. Thereby, the adsorption (supply) of the etchant to the recess 4 and the etching can be promoted. In addition, HF is on or high controlled during period A. As a result, because the plasma generation is promoted during period A, the adsorption amount of the etchant increases and the etching is promoted. On the other hand, during period B, LF is controlled to be on or high, the amount of ions in the plasma drawn to the substrate is increased to increase the heat input from the plasma, and the temperature of the substrate is increased. Thereby, the discharge (desorption) of the reaction product by the etching can be promoted. In addition, HF is controlled to be off or low during period B. As a result, the amount of the plasma generated is reduced and the amount of the etchant adsorbed to the recess 4 is reduced, thereby reducing the amount of the reaction product generated.

As described above, in the fifth embodiment, in addition to pulse control of LF, by pulse control of HF, the supply amount of the etchant, the promotion of the etching, and the discharge of the reaction product can be controlled. That is, the increase in the etchant supply amount and the promotion of the etching by decreasing the temperature of the substrate in period A and the decrease in the etchant supply amount and the discharge (desorption) of the reaction product by increasing the temperature of the substrate in period B are alternately repeated. As a result, the discharge efficiency of the reaction product 5 can be increased, the occurrence of depth loading can be suppressed, and the etching can be promoted. Additionally, the shape of the recess 4 can be further improved.

It should be noted that although an example is described in which the waveform of LF and/or the waveform of HF are square waves in the fourth and fifth embodiments, the present disclosure is not limited thereto. As the waveform of LF and the waveform of HF, not only a square wave but also a substantially square wave including at least one of slow-up rising and slow-down falling may be applied. The same shall apply to a sixth embodiment.

### Sixth Embodiment

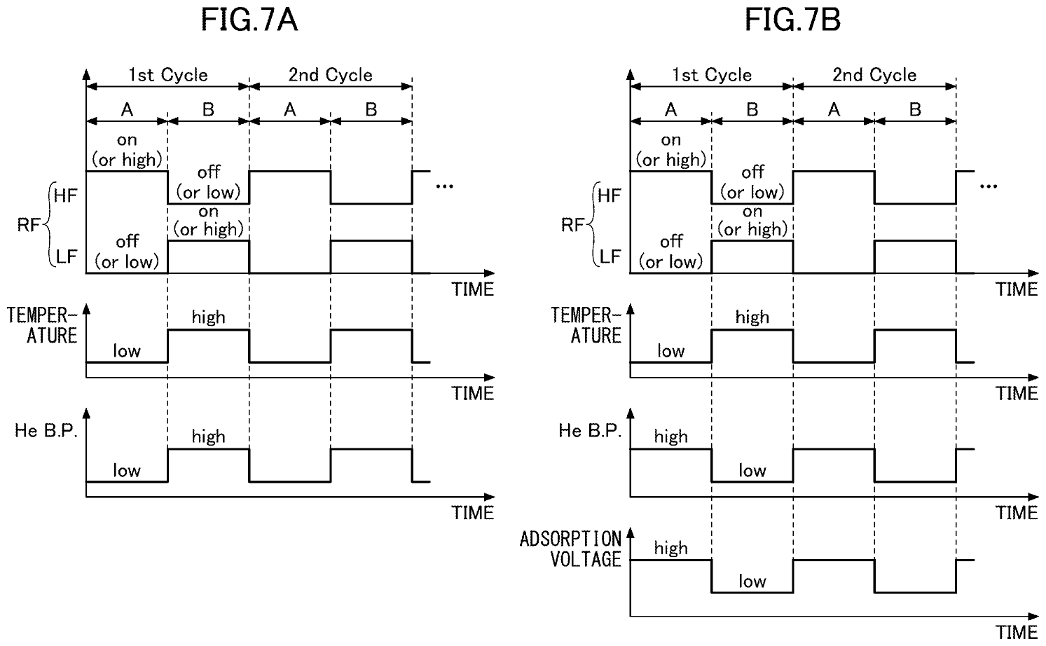

Next, an example of an etching method according to a sixth embodiment that is an example of the third embodiment will be described with reference to FIGS. 7A and 7B. FIGS. 7A and 7B illustrate a time chart illustrating an example of an etching method according to the sixth embodiment. As illustrated in FIGS. 7A and 7B, the etching method according to the sixth embodiment differs from that according to the fifth embodiment in that a heat transfer medium supplied between the substrate support stage 20 and the substrate W is supplied with increasing/decreasing the pressure in a pulsed manner. Further, as illustrated in FIG. 7B, the sixth embodiment differs from the fifth embodiment in that a heat transfer medium supplied between the substrate support stage 20 and the substrate W and an adsorption voltage of the electrostatic chuck 106 to the electrode 106a of FIG. 8, which will be described later below, are supplied in a pulsed manner. It should be noted that although the sixth embodiment is the same as the fifth embodiment in that LF and HF are pulse-controlled, LF may be pulse-controlled and HF may be a continuous wave similarly to the fourth embodiment.

The supply of the heat transfer medium enhances the heat transfer efficiency between the substrate support stage 20 and the substrate W. Therefore, the temperature of the substrate can be changed by changing the pressure between the substrate support stage 20 and the substrate W by controlling the flow rate of the heat transfer medium. It should be noted that although He gas is used as the heat transfer medium in the sixth embodiment, another inert gas may be used.

Specifically, in the sixth embodiment, LF is controlled to be off or low during period A and LF is controlled to be on or high during period B. In addition, HF is controlled to be on or high during period A and HF is controlled to be off or low during period B.

In addition, in the sixth embodiment, the pressure (He B.P.: He Back Pressure) between the back surface of the substrate W and the front surface of the substrate support stage 20 is controlled. As an example, a heat transfer medium, such as He gas, is supplied from a heat transfer gas supply source 85 through a heat transfer gas line 130 between the back surface of the substrate W and the surface of the substrate support stage 20, and the flow rate thereof is controlled to be high or low. Also, the temperature control medium (temperature control fluid) is controlled to be a desired temperature by a chiller 107 illustrated in FIG. 8. The temperature control medium is output from the chiller 107, flows into a flow path inlet 104b, flows out from a flow path outlet 104c through the flow path 104a, and returns to the chiller 107. In the sixth embodiment, in a case in which a temperature control medium is supplied by the chiller 107 to flow through the flow path 104a, the flow rate of He gas is changed to control the pressure between the back surface of the substrate W and the surface of the substrate support stage 20.

In a case in which the temperature of the temperature control medium controlled by the chiller 107 is higher than a predetermine threshold temperature, the flow rate of He gas is controlled to be low during the period A as illustrated in FIG. 7A to reduce the pressure between the back surface of the substrate W and the surface of the substrate support stage 20. In this way, during period A, the heat transfer efficiency is reduced to make it difficult to transfer the temperature of the substrate support stage 20 heated by the temperature control medium flowing through the flow path of the substrate support stage 20 to the substrate W, thereby reducing the temperature of the substrate W. Thereby, the adsorption (supply) of the etchant to the recess 4 and the etching can be promoted. On the other hand, during period B, the pressure between the back surface of the substrate W and the front surface of the substrate support stage 20 is increased by controlling the flow rate of He gas to be a high level. Thus, during period B, the heat transfer efficiency is increased to make it easier to transfer the temperature of the substrate support stage 20 heated by the temperature control medium to the substrate W, thereby increasing the temperature of the substrate. Thereby, the discharge (desorption) of the reaction product 5 from the recess 4 can be promoted.

In a case in which the temperature of the temperature control medium controlled by the chiller 107 is below a predetermined threshold temperature, the pressure between the back surface of the substrate W and the front surface of the substrate support stage 20 is increased by controlling the flow rate of He gas to be high during period A, as illustrated in FIG. 7B. Thus, during period A, the heat transfer efficiency is increased to make it easier to transfer the temperature of the substrate support stage 20 cooled by the temperature control medium to the substrate W, thereby lowering the temperature of the substrate. Thereby, the adsorption of the etchant to the recess 4 and the etching can be promoted. On the other hand, during period B, the pressure between the back surface of the substrate W and the front surface of the substrate support stage 20 is reduced by controlling the flow rate of He gas to be low. In this way, during period B, the heat transfer efficiency is reduced to make it difficult to transfer the temperature of the substrate support stage 20 to the substrate W, thereby increasing the temperature of the substrate W. Thereby, the discharge of the reaction product 5 from the recess 4 can be promoted.

In addition, the adsorption voltage of the electrostatic chuck 106 to electrode 106a of FIG. 8 may be controlled to be high or low. By changing the adsorption voltage of the electrostatic chuck 106, the heat transfer characteristics between the electrostatic chuck 106 and the substrate W can be changed to adjust the temperature of the substrate W. For example, increasing the adsorption voltage to the electrostatic chuck 106 increases the thermal conductivity, and decreasing the adsorption voltage decreases the thermal conductivity. Thereby, the temperature of the substrate W can be changed.

For example, in FIG. 7B, the adsorption voltage is controlled to be high during period A. Thus, during period A, the heat transfer efficiency is increased to make it easier to transfer the temperature of the substrate support stage 20 cooled by the temperature control medium to the substrate W, thereby lowering the temperature of the substrate. Thereby, the adsorption of the etchant to the recess 4 and the etching can be promoted. The adsorption voltage is controlled to be low during period B. Thus, during period B, the heat transfer efficiency is reduced to make it difficult to transfer the temperature of the substrate support stage 20 cooled by the temperature control medium to the substrate W, thereby increasing the temperature of the substrate W. Thereby, the exhaust of the reaction product 5 from the recess 4 can be promoted. The period of controlling the adsorption voltage to be high and the period of controlling the adsorption voltage to be low are switched by the control temperature of the temperature control medium. Although not illustrated, in a case in which the temperature of the substrate support stage 20 is heated by the temperature control medium in FIG. 7A, the adsorption voltage is controlled to be low during period A and is controlled to be high during period B.

By using at least one of LF control, HF control, pressure control between the back surface of the substrate W and the front surface of the substrate support stage 20 by a heat transfer medium, temperature control of the chiller 107, and adsorption voltage control of the electrostatic chuck 106 as described above, the temperature of the substrate W can be increased/decreased and step S4 and step S5 of FIG. 3 can be executed. Further, by using at least two of LF control, HF control, pressure control between the back surface of the substrate W and the front surface of the substrate support stage 20 by a heat transfer medium, temperature control of the chiller 107, and adsorption voltage control of the electrostatic chuck 106, the temperature of the substrate W may be increased/decreased.

Specifically, FIG. 4 is an example in which the temperature of the substrate W is controlled by high and low control or on and off control of LF power. FIG. 6 is an example in which the temperature of the substrate W is changed by high and low control or on and off control of HF power and LF power. FIG. 7A is an example in which the temperature of the substrate W is controlled by high and low control or on and off control of HF power and LF power and the pressure of He. FIG. 7B is an example in which the temperature of the substrate W is controlled by high and low control or on and off control of HF power and LF power, the pressure of He, and the adsorption voltage to the electrode 106a of the electrostatic chuck 106. In each of the specific examples of FIG. 4, FIG. 6 and FIG. 7A, the temperature can be changed by control to further change the adsorption voltage to the electrode 106a of the electrostatic chuck 106.

In FIG. 4 and FIG. 6, for example, when the low temperature control medium is flowing through the substrate support stage 20, the adsorption voltage is controlled to be high when LF is controlled to be low and the adsorption voltage is controlled to be low when LF is controlled to be high. Therefore, the substrate temperature can be effectively lowered in period A, and the substrate temperature can be efficiently increased in period B. In other examples, the timing of controlling the adsorption voltage to high or low differs depending on the temperature of the temperature control medium controlled by the chiller. In this example, the pressure of the heat transfer medium may be made high or low in accordance with the high or low of the adsorption voltage.

As described above, in the sixth embodiment, in addition to pulse control of LF, thermal conduction of He gas supplied between the substrate support stage 20 and the substrate W is controlled. Thereby, by promoting the temperature decrease of the substrate during period A and the temperature increase of the substrate during period B in each cycle, the etching can be promoted during period A and the discharge of the reaction product 5 can be promoted during period B. By repeating this a predetermined number of times, the promotion of the etching and the discharge of the reaction product are performed alternately. Thereby, the discharge efficiency of the reaction product can be further increased, the occurrence of depth loading can be effectively suppressed, and the etching can be effectively promoted. In addition, the shape of the recess 4 can be improved to be a favorable vertical shape.

It should be noted that in the sixth embodiment, only the pulse control of the pressure by He gas may be performed without performing the pulse control of LF.

### Etching Apparatus

An example of an etching apparatus 1 capable of executing an etching method according to each embodiment and each embodiment will be described with reference to FIG. 8. FIG. 8 is a cross-sectional view illustrating an example of the etching apparatus 1 according to the embodiment. The etching apparatus 1 of the present disclosure includes a process chamber 10, a gas supply source 15, a power source 30, an exhaust device 65 and a controller 100. The etching apparatus 1 also includes a substrate support stage 20 and a gas introduction section. The gas introduction section is configured to introduce at least one process gas into the process chamber 10. The gas introduction section includes a showerhead 25. The substrate support stage 20 is arranged within the process chamber 10. The showerhead 25 is arranged above the substrate support stage 20. In one embodiment, the showerhead 25 constitutes at least portion of the ceiling of the process chamber 10. A ring-shaped insulating member 40 is arranged around the outer periphery of the showerhead 25. The process chamber 10 has a plasma process space 10s defined by the showerhead 25, a side wall 10a of the process chamber 10, and the substrate support stage 20. The process chamber 10 has a gas supply port 45 for supplying at least one process gas to the plasma process space 10s and a gas discharge port 60 for discharging gas from the plasma process space 10s. The side wall 10a of the process chamber 10 is grounded. The showerhead 25 and substrate support stage 20 are electrically isolated from the housing of the process chamber 10. A transport port is provided on the side wall 10a, and the substrate W is carried into the process chamber 10 and the substrate W is carried out from the process chamber 10 by opening and closing the transport port with the gate valve G.

The substrate support stage 20 includes a base 104 and an electrostatic chuck 106. The base 104 and the showerhead 25 include an electrically conductive member. The electrically conductive member of the base 104 functions as a lower electrode. The electrostatic chuck 106 is arranged on the base 104. The upper surface of the electrostatic chuck 106 has a substrate support surface. The electrostatic chuck 106 has a configuration in which an electrically conductive electrode 106a is embedded in an insulating plate 106b.

The substrate support stage 20 may include a temperature control module configured to adjust at least one of the substrate support stage 20 and the substrate W to a target temperature. The temperature control module may include a heater, a temperature control medium, a flow path, or a combination thereof. In the present disclosure, a flow path 104a is provided in the base 104, and a temperature control medium, such as brine, is controlled to a desired temperature by a chiller 107. The temperature control medium is supplied by the chiller 107, flows from a flow path inlet 104b, flows through the flow path 104a, flows out a flow path outlet 104c, and returns to the chiller 107. Also, a heat transfer medium, such as He gas, is supplied from a heat transfer gas supply source 85 through a heat transfer gas line 130 between the back surface of the substrate W and the front surface of the substrate support stage 20.

The showerhead 25 is configured to introduce at least one processing gas from the gas supply source 15 into the plasma process space 10s. The showerhead 25 includes at least one gas supply port 45 and at least one gas diffusion chamber (in the example of FIG. 8, gas diffusion chambers 50a and 50b, and a plurality of gas introduction ports 55). The process gas supplied to the gas supply port 45 is introduced into the plasma process space 10s from the plurality of gas introduction ports 55 through the gas diffusion chambers 50a and 50b. It should be noted that the gas introduction section may include, in addition to the showerhead 25, one or more side gas injection sections (SGI: Side Gas Injectors) attached to one or more openings formed in the side wall 10a.

The gas supply source 15 has at least one gas source and is configured to supply at least one process gas from each corresponding gas source to the showerhead 25 via a corresponding flow controller. Each flow controller may include, for example, a mass flow controller or a pressure controlled flow controller. In addition, the gas supply source 15 may include one or more flow modulation devices that modulate or pulse the flow rate of the at least one process gas.

A power source 30 includes an RF power source coupled to the process chamber 10 via at least one matching device (impedance matching circuit). The RF power source is configured to provide at least one RF signal (RF power), such as a source RF signal and a bias RF signal, to the electrically conductive member of the substrate support stage 20 and/or the electrically conductive member of the showerhead 25. Thereby, plasma is formed from at least one process gas supplied to the plasma process space 10s. Accordingly, the RF power source may function as at least a portion of a plasma generator that is configured to generate plasma from one or more process gases in the process chamber 10. In addition, by supplying a bias RF signal to the electrically conductive member of the substrate support stage 20, a bias potential is generated at the substrate W, and ion components in the formed plasma can be drawn into the substrate W.

In one embodiment, the RF power source includes a radio frequency power source 32 that supplies radio frequency power for plasma generation and a radio frequency power source 34 that supplies radio frequency power for bias. The radio frequency power source 32 is coupled to the electrically conductive member of the substrate support stage 20 via a first matching device 33 and is configured to generate a source RF signal (source RF power) for plasma generation. In the present disclosure, the radio frequency power source 32 is coupled to the base 104, which is an electrically conductive member of the substrate support stage 20, but may be coupled to an electrically conductive member of the showerhead 25.

In one embodiment, the power source 30 may include a first RF generator configured to generate a plurality of source RF signals having different frequencies. The generated one or more source RF signals are supplied to the electrically conductive member of the substrate support stage 20 and/or the electrically conductive member of the showerhead 25. The radio frequency power source 34 is coupled to the electrically the electrically conductive member of the substrate support stage 20 via a second matching device 35 and is configured to generate a bias RF signal (bias RF power). In one embodiment, the bias RF signal has a lower frequency than that of the source RF signal. In one embodiment, the power source 30 may include a second RF generator configured to generate a plurality of bias RF signals having different frequencies. The generated one or more bias RF signal are supplied to the electrically conductive member of the substrate support stage 20. Also, in various embodiments, at least one of the source signals and the bias RF signals may be pulsed.

Also, there may be a DC power source that is coupled to the process chamber 10. The DC power source may have a first DC generator that is connected to the electrically conductive member of the substrate support stage 20 and that is configured to generate a first DC signal. The generated first DC signal is applied to the electrically conductive member of the substrate support stage 20. In one embodiment, the first DC signal may be applied to another electrode such as the electrode 106a in the electrostatic chuck 106. In one embodiment, a DC voltage is applied from the DC power source 112 to the electrode 106a in the electrostatic chuck 106, and thus the substrate W is adsorbed and held by the electrostatic chuck 106. In various embodiments, at least one of the first DC signals may be pulsed. It should be noted that the first DC generator may be provided in addition to the RF power source, and the first DC generator may be provided in place of a second RF generator, which will be described later.

An exhaust device 65 may be connected, for example, to the gas discharge port 60 provided at the bottom of the process chamber 10. The exhaust device 65 may include a pressure regulating valve and a vacuum pump. The pressure regulating valve regulates the pressure in the plasma process space 10s. The vacuum pump may include a turbomolecular pump, a dry pump, or a combination thereof.

The controller 100 processes computer-executable instructions that cause the etching apparatus 1 to execute various steps described in the present disclosure. The controller 100 may be configured to control each element of the etching apparatus 1 so as to execute the respective steps of various etching methods described herein. In one embodiment, part or all of the controller 100 may be included in the etching apparatus 1. The controller 100 may include, for example, a computer. The computer may include, for example, a central processing unit (CPU) 105, a storage, and a communication interface. The processing unit 105 may be configured to perform various control operations based on a program stored in the storage. The storage includes a RAM 115 (Random Access Memory) and a ROM 110 (Read Only Memory). The storage may include an

HDD (hard disk drive), a SSD (solid state drive), or a combination thereof. The communication interface may communicate with the etching apparatus 1 via a communication line such as a LAN (Local Area Network).

### Others

The etching target film 3 may be a silicon-containing film. Examples of the silicon-containing film include a silicon oxide film, a silicon nitride film, a layered film of a silicon oxide film and a silicon nitride film, a layered film of a silicon oxide film and a polysilicon film, and the like. However, the etching target film 3 is not limited to a silicon-containing film, and may be an organic film, a Low-K film, or another desired film.

The mask 2 may be of any type as long as it has a selective ratio with that of the etching target film 3. For example, in a case in which where the etching target film 3 is a silicon oxide film, a silicon nitride film, a layered film of a silicon oxide film and a silicon nitride film, or a layered film of a silicon oxide film and a polysilicon film, a carbon-containing mask or a metal-containing mask may be used. In a case in which the etching target film 3 is an organic film, a mask made of a silicon oxide film or the like may be used.

As the etching gas, a halogen-containing gas (e.g., fluorocarbon gas, hydrofluorocarbon gas, etc., NF₃ gas, SF₆ gas, and a combination thereof) may be used in a case in which the etching target film 3 is a silicon-containing film. In addition, an inert gas, such as Ar gas, may be added to these gases as a noble gas.

### Clause 1

In the above, an etching method has been described including (a) providing a substrate including an etching target film on a substrate support stage arranged in a process chamber; (b) setting a temperature of the substrate support stage; (c) generating plasma from an etching gas; (d) increasing the temperature of the substrate; (e) decreasing the temperature of the substrate; and (f) repeating (d) and (e) a predetermined number of times. Increasing the temperature of the substrate in (d) may be a step of desorbing the reaction product generated by the etching of the etching target film. Decreasing the temperature of the substrate of (e) may be a step of causing the etchant to be adsorbed on the etching target film.

### Clause 2

In one embodiment, the DC power source that is coupled to the process chamber 10 may include a second DC generator that is connected to the electrically conductive member constituting the showerhead 25 and that is configured to generate a second DC signal. The generated second DC signal is applied to the electrically conductive member constituting the showerhead 25. In various embodiments, the second DC signal may be pulsed. It should be noted that the second DC generator may be configured to superimpose and apply the RF power from the RF power source coupled to the electrically conductive member.

### Clause 3

In the sixth embodiment, an example of controlling the pressure between the back surface of the substrate W and the front surface of the substrate support stage 20 by controlling the flow rate of the heat transfer medium such as He gas in a state in which the chiller 107 controls the temperature control medium at a constant temperature (high temperature or low temperature) is described, but the present disclosure is not limited thereto. For example, the temperature of the substrate may be controlled by at least one of the temperature control of the temperature control medium by the chiller 107 and the pressure control of the heat transfer medium. In temperature control by the chiller 107, a temperature control medium controlled at a high temperature and a temperature control medium controlled at a low temperature may be prepared respectively in two tanks and the respective flow rates of the high temperature control medium and the low temperature control medium supplied from the two tanks may be adjusted to supply a temperature control medium at a desired temperature to the flow path 104a. Also, in the temperature control by the chiller 107, a temperature control medium may be stored in one tank and the temperature control medium may be supplied to the flow path 104a while adjusting the temperature control medium in the tank to the desired temperature. In the sixth embodiment, pulse control of LF may be performed or may not be performed, and at least one of the pressure control by the heat transfer medium and the temperature control of the temperature control medium by the chiller 107 may be performed.

### Clause 4

In one embodiment, the temperature of the substrate in (e) may be 120° C. or more and 40° C. or less.

As described above, according to the etching method and the etching apparatus of each embodiment and each example, it is possible to promote the etching while suppressing the occurrence of depth loading. Further, the shape of the recess 4 of the etching target film 3 can be made favorable. For example, in a case in which an etching target film 3 is etched into a pattern of a mask 2 having different diameters or widths, the difference in etching rates of the recesses 4 having different diameters or widths can be reduced.

An etching method and an etching apparatus according to each embodiment and each example disclosed herein should be considered exemplary in all respects and are not limited thereto. Each embodiment and each example as described above may be changed and modified in various forms without departing from the appended claims and spirit thereof. The matters described in the embodiments as described above may take other configurations to the extent not inconsistent, and may be combined to the extent not inconsistent.

An etching apparatus according to the present embodiment can be applied to any type of apparatuses such as a Capacitively Coupled Plasma (CCP) apparatus, an Inductively Coupled Plasma (ICP) apparatus, a Radial Line Slot Antenna (RLSA) apparatus, an Electron Cyclotron Resonance Plasma (ECR) apparatus, and a Helicon Wave Plasma (HWP) apparatus.

What is claimed is:

1. An etching method comprising:
(a) providing a substrate including an etching target film on a substrate support stage arranged in a process chamber;
(b) setting a temperature of the substrate support stage;
(c) generating plasma from an etching gas;
(d) increasing the temperature of the substrate;
(e) decreasing the temperature of the substrate; and
(f) repeating (d) and (e) a predetermined number of times.

2. The etching method according to claim 1,
wherein in (d), supply of a radio frequency power for bias is controlled to be ON, and
wherein in (e), supply of the radio frequency power for bias is controlled to be OFF.

3. The etching method according to claim 1,
wherein in (d), supply of a radio frequency power for bias is controlled to be high, and
wherein in (e), supply of the radio frequency power for bias is controlled to be low.

4. The etching method according to claim 1, further comprising:
(i) supplying a heat transfer medium between the substrate and the substrate support stage,
wherein in a case in which a temperature control medium that is output from a chiller and that has a temperature lower than a predetermined threshold temperature flows through a flow path formed in the substrate support stage, a flow rate of the heat transfer medium is controlled so as to decrease a pressure between the substrate and the substrate support stage in (d) and the flow rate of the heat transfer medium is controlled so as to increase the pressure in (e).

5. The etching method according to claim 1,
(i) supplying a heat transfer medium between the substrate and the substrate support stage,
wherein in a case in which a temperature control medium that is output from a chiller and that has a temperature higher than a predetermined threshold temperature flows through a flow path formed in the substrate support stage, a flow rate of the heat transfer medium is controlled so as to increase a pressure between the substrate and the substrate support stage in (d) and the flow rate of the heat transfer medium is controlled so as to decrease the pressure in (e).

6. The etching method according to claim 1,
wherein the substrate support stage includes an electrostatic chuck including an electrode,
wherein the method further includes
(j) supplying an adsorption voltage to the electrode,
wherein in a case in which a temperature control medium that is output from a chiller and that has a temperature lower than a predetermined threshold temperature flows through a flow path formed in the substrate support stage, the adsorption voltage supplied to the electrode is controlled to be low in (d) and the adsorption voltage supplied to the electrode is controlled to be high in (e).

7. The etching method according to claim 1,
wherein the substrate support stage includes an electrostatic chuck including an electrode,
wherein the method further includes
(j) supplying an adsorption voltage to the electrode,
wherein in a case in which a temperature control medium that is output from a chiller and that has a temperature higher than a predetermined threshold temperature flows through a flow path formed in the substrate support stage, the adsorption voltage supplied to the electrode is controlled to be high in (d) and the adsorption voltage supplied to the electrode is controlled to be low in (e).

8. The etching method according to claim 1, wherein in (e), the temperature of the substrate is lowered to a temperature at which an etchant of the etching gas is adsorbed on the substrate.

9. The etching method according to claim 8, wherein the temperature of the substrate in (e) is −120° C. or more and 40° C. or less.

10. The etching method according to claim 9, wherein the temperature of the substrate in (e) is −40° C. or more and 20° C. or less.

11. The etching method according to claim 1, wherein the temperature of the substrate is increased to a temperature at which a reaction product generated by etching the substrate volatilizes in (d).

12. The etching method according to claim 1, wherein a difference in the temperature of the substrate between (d) and (e) is 10° C. or more.

13. The etching method according to claim 1, wherein a frequency of one cycle of repeating (f) is 0.1 Hz or more and 100 kHz or less.

14. The etching method according to claim 13, wherein a duty cycle indicating a time of (d) with respect to a time of the one cycle is 30% or more and 50% or less.

15. The etching method according to claim 14, wherein the duty cycle is 30% or more and 50% or less.

16. An etching method comprising:
(a) providing a substrate including an etching target film on a substrate support stage;
(b) setting a temperature of the support stage or the substrate;
(c) generating plasma from an etching gas and etching the substrate;
(d) increasing the temperature of the substrate;
(e) decreasing the temperature of the substrate; and
(f) repeating or combining (d) and (e).

17. An etching apparatus for etching an etching target film included in a substrate, the etching apparatus comprising:
a process chamber;
a substrate support stage arranged in the process chamber;
a plasma generator configured to generate plasma from an etching gas; and
a controller,
wherein the controller is configured to execute a process including
(b) setting a temperature of the substrate support stage;
(c) generating the plasma from the etching gas;
(d) increasing the temperature of the substrate;
(e) decreasing the temperature of the substrate; and
(f) repeating (d) and (e) a predetermined number of times.
